(19) United States
(12) Patent Application Publication
(10) Pub. No.: US 2013/0016467 A1
(43) Pub. Date: Jan. 17, 2013

(54) LEATHER CASE WITH KEYBOARD

(71) Applicant: ALLEN KU, WALNUT, CA (US)

(72) Inventor: ALLEN KU, WALNUT, CA (US)

(21) Appl. No.: 13/179,979

(22) Filed: Jul. 11, 2011

(51) Int. Cl. H05K 5/03

(52) U.S. Cl. 361/679.08

(57) ABSTRACT

A leather case with keyboard includes a folding cover, a base, and a keyboard. The folding cover has a first support portion bendably connected to a second support portion. A bending portion is formed therebetween. The base is bendably connected to the first support portion and has a securing member. A receiving region is defined by the securing member and the base to accommodate the keyboard removably. A leather case assembly with keyboard is also disclosed.

### BACKGROUND OF THE INVENTION

1. Field of the Invention

The instant disclosure relates to a leather case with keyboard; more particularly, to a leather case with keyboard for receiving a flat electronic device and a leather case assembly with keyboard.

2. Description of Related Art

The tablet personal computers, or Tablet PCs, are becoming more popular in today's commercial market. In 2002, Microsoft released the Windows XP Tablet PC Edition, which is an operating system (OS) to specifically support the Tablet PCs. Since then, more Tablet PCs have surfaced in the commercial market that was traditionally filled by desktop and laptop computers. Microsoft has since lunched “The New Generation Tablet PC”. In 2007, the iPhone, which is an internet- and multimedia-enabled smart phone with multi-touch screen, is introduced by Apple. First used by the military and other special applications, the touchscreens have subsequently become familiar in everyday life. For example, the touchscreen technology has been used on tablet computers, smart phones, mini notebooks, and other portable electronics. The user can listen to music, play on-line video games, draw, read e-book, watch movies, and surf internet by interfacing through the touchscreen as the primary input device. Such technological advancement has redefined the way people live and work. Therefore, electronics that include touchscreens, which provide visual displays and can detect the presence and location of a touch within the display area, are gaining much popularity among the consumers.

Most protective cases for the consumer electronics provide portability and protection against impact and vibration. To use the electronic device, the protective case is opened and laid on a flat support structure. However, under some circumstances, such as word processing, these electronic devices need to be used along with the keyboards. Currently, most leather cases in the market do not provide accommodation for the keyboards. Word inputs have to be interfaced through the touchscreens. The system takes time to verify the inputs, which is time-consuming and inconvenient for the users.

To address the above issues, the inventor strives via industrial experience and academic research to present the instant disclosure, which can effectively improve the limitations described above.

### SUMMARY OF THE INVENTION

The instant disclosure provides a leather case having a keyboard. The leather case comprises a folding cover, a base, and a keyboard. The folding cover has a first support portion and a second support portion. The second support portion is bendably connected to the first support portion in forming a bending portion. The second support portion has a first holding member. The base is bendably connected to the first support portion and has a securing member. A receiving region to accommodate the keyboard is defined by the securing member and the base. The keyboard may be removably disposed in the receiving region.

The instant disclosure further provides a leather case assembly, which comprises a folding cover, a base, a keyboard, and a flat electronic device. The folding cover has a first support portion and a second support portion. The second support portion is bendably connected to the first support portion in forming a bending portion. The second support portion has a first holding member. The base is bendably connected to the first support portion and has a securing member. A receiving region to accommodate the keyboard is defined by the securing member and the base. The keyboard may be removably disposed in the receiving region. The flat electronic device is secured by the first holding member and connected electrically to the keyboard.

For the leather case of the instant disclosure, the flat electronic device can be selectively received therein. By adjusting the angle of the leather case, the flat electronic device can be arranged at different angle. Thus, the flat electronic device can be used more conveniently with the keyboard.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is an exploded view of a leather case having a keyboard of the instant disclosure.

FIG. 2 is an exploded view of a leather case having a keyboard for another embodiment of the instant disclosure.

FIG. 3 is a schematic view of a leather case assembly in use of the instant disclosure.

FIG. 4 is another schematic view of the leather case assembly in use of the instant disclosure.

FIG. 5 is further another schematic view of the leather case assembly in use of the instant disclosure.

### DETAILED DESCRIPTION OF PREFERRED EMBODIMENTS

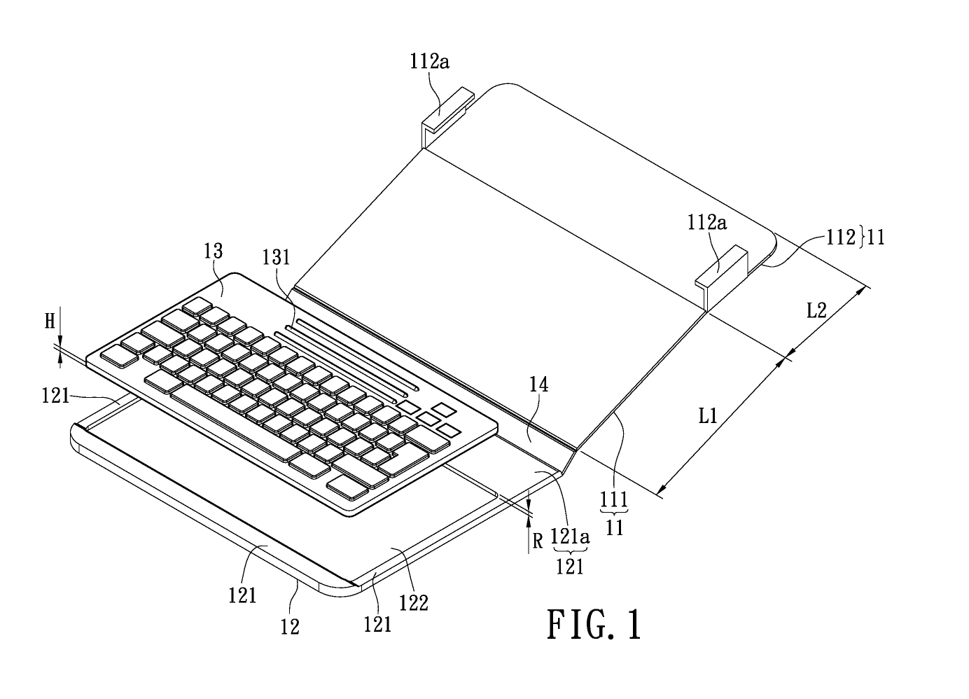

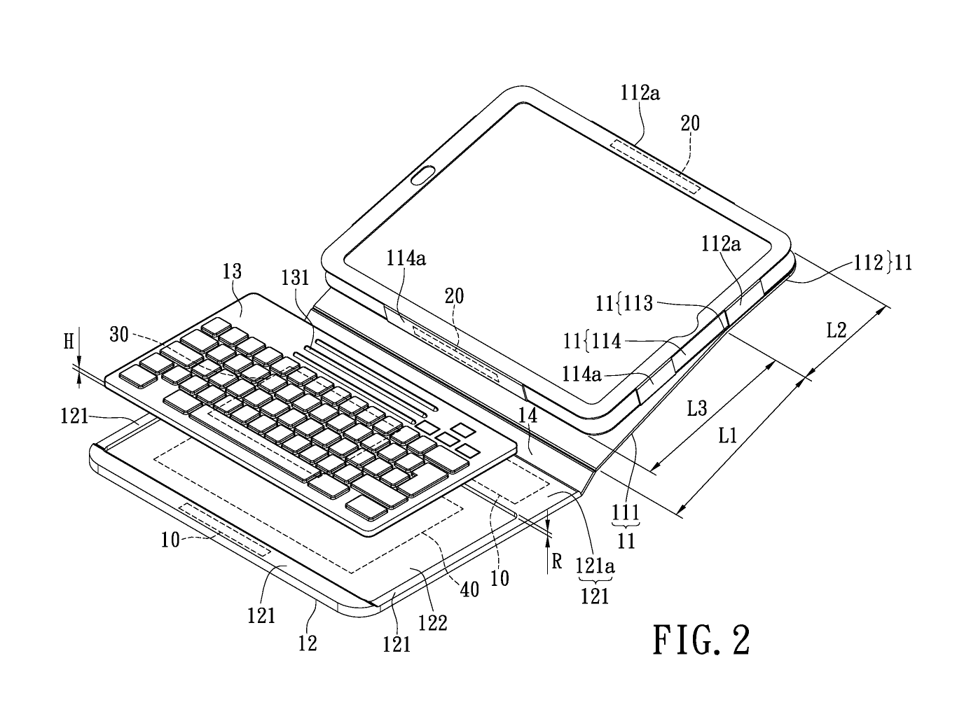

Please refer to FIG. 1. The instant disclosure provides a leather case 1, which comprises a folding cover 11, a base 12, and a keyboard 13. The folding cover 11 has a first support portion 111 and a second support portion 112. The second support portion 112 is bendably connected to the first support portion 111 in forming a bending portion 113 therebetween (FIG. 2). The base 12 is also bendably connected to the first support portion 111. Thus, based on needs, the user can adjust the angle of the bending portion 113 and the angle between the base 12 and the first support portion 111. Thereby, the leather case can be set up having different angles with much flexibility.

The base 12 has a securing member 121. A receiving region 122 is defined by the securing member 121 and the base 12. The keyboard 13 can be selectively disposed in the receiving region 122. Furthermore, the second support portion 12 has at least one first holding member 112a formed thereon. The first holding member 112a can be used to secure a flat electronic device (not shown). Therefore, the leather case 1 of the instant disclosure can selectively receive the flat electronic device. The flat electronic device and the keyboard 13 can co-exist in the leather case 1. Besides providing portability, the leather case 1 allows the flat electronic device to be used alongside with the keyboard 13 as a complete unit.

Please refer to FIG. 2, which shows an exploded view of a leather case 1 for another embodiment of the instant disclosure. As shown in FIG. 2, the leather case 1 comprises the folding cover 11, the base 12, and the keyboard 13. The securing member 121 of the base 12 is formed with a frame-like structure 121a. The frame-like structure 121a has a predetermined thickness R, which defines the receiving region 122 bounded by the base 12 on the bottom. Since the keyboard 13 is defined having a thickness H, the keyboard 13 can be precisely secured to the receiving region 122 defined by the frame-like structure 12a of thickness R and the base 12. The shape of the keyboard 13 also matches with the shape of the receiving region 122. Therefore, the keyboard 13 can be completely received by the receiving region 122 without occupying any extra space. Hence, the leather case 1 provides portability and is aesthetically appealing. The leather case 1 can be made of real or synthetic leather. For example, the artificial leather may be made by polyurethane. The keyboard 13 may be made of hard plastic or soft silicone rubber with no material restriction.

For the instant embodiment, to further secure the keyboard 13 in the receiving region 122, a third magnet/magnetic member 30 can be disposed on the keyboard 13. Correspondingly, a fourth magnet/magnetic member 40 can be disposed on the base 12. The third and fourth magnet/magnetic member 30 and 40 are arranged to complement each other, such that the keyboard 13 is more firmly secured to the receiving region 122 by the attraction between third magnet/magnetic member 30 and the fourth magnet/magnetic member 40. The shape, quantity, material, and arrangement of the third and fourth magnet/magnetic member 30 and 40 are not restricted. For example, the third magnet/magnetic member 30 and the fourth magnet/magnetic member 40 can be a pair of complementing magnet and magnetic member unit, with plate-, strip-, or circular-liked shape. For the instant embodiment, the third magnet/magnetic member 30 can be a plate-shaped magnet receivebly disposed on the keyboard 13, and the fourth magnet/magnetic member 40 can be an iron strip.

As shown in FIG. 2, at least one first magnet/magnetic member 10 is disposed on the securing member 121 of the base 12. At least one of the second magnet/magnetic member 20 is disposed on the first holding member 112a on the top edge of the folding cover 11. Thereby, the leather case 11 can be kept closed by magnetic attraction between the first magnet/magnetic member 10 and the second magnet/magnetic member 20 on the base 12 and the folding cover 11, respectively. Furthermore, the leather case 1 can further include a spine 14 bendably connected between the first support portion 111 and the base 12. The spine 14 acts as a pivoting axis for opening or closing the leather case 1.

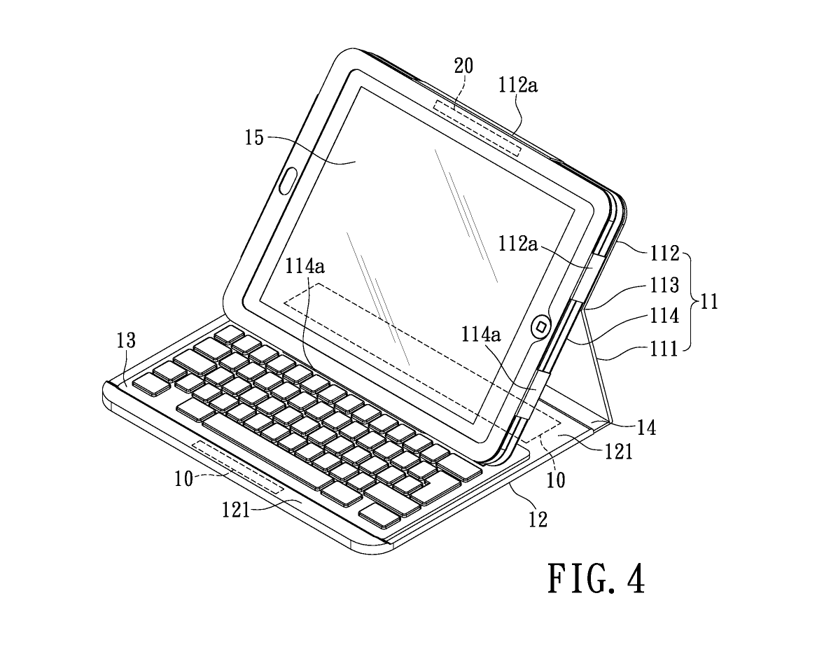

Notably, the second support portion 112 can further be extended to form a support frame 114. A second holding member 114a is formed on the support frame 114. Thereby, an accommodating space (not labeled) is defined by the first holding member 112a and the second holding member 114a, for securing and protecting the flat electronic device therein. In addition, at least one display-rest 131 is formed on the keyboard 13. The quantity, shape, and arrangement of the display-rest 131 are not restricted. For the instant embodiment, three display-rests 131 formed of long slots are arrayed on the keyboard 13 in parallel with the adjacent side of the support frame 114. As shown in FIG. 4, when using the leather case 1, the support frame 114 can selectively abuts against one of the display-rest 131, to change the viewing angle of the flat electronic device.

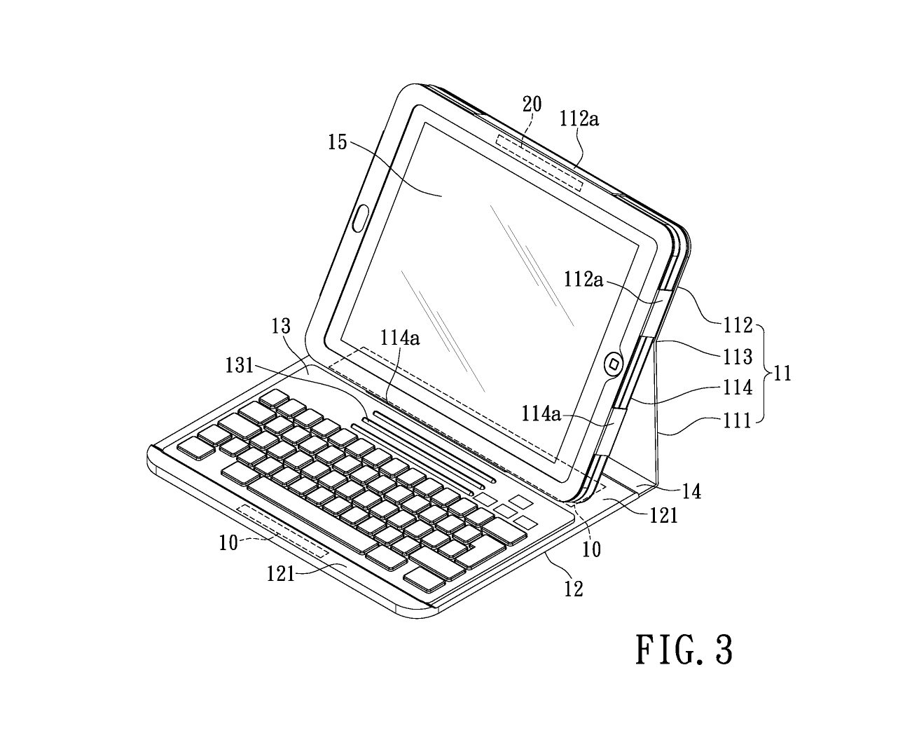

Please refer to FIGS. 3˜5, which show a leather case assembly 2 of the instant disclosure. The leather case assembly 2 includes the folding cover 11, the base 12, the keyboard 13, and a flat electronic device 15. The structural descriptions of the folding cover 11, the base 12, and the keyboard 13 are the same as discussed earlier, therefore are not repeated. The folding cover 11 has the first support portion 111 and the second support portion 112. The second support portion 112 has at least one first holding member 112a to secure the flat electronic device 15. The flat electronic device 15 is electrically connected to the keyboard 13, which provide a means for interfacing the flat electronic device 15 conveniently.

As shown in FIGS. 3˜5, the flat electronic device 15 can be firmly received by the accommodating space (not labeled) formed by the first holding member 112a and the second holding member 114a. Thus, the flat electronic device 15 is prevented from being shakingly disposed thereto and accidental displacement from the leather case. Thereby, a smooth user operation can be ensured. Please refer back to FIG. 2. The first support portion 111 has a width L1, and the second support portion 112 has a width L2, which is less than L1. The support frame 114 has a width L3 smaller than or equal to L1. When the flat electronic device 15 is secured on the second support portion 112, the first support portion 111 provides support for the flat electronic device 15. The bending portion 133 can be bent, to move the support frame 114 toward or away from the first support portion 111. Thus, the flat electronic device 15 can be arranged at different angles accordingly.

Notably, when the leather case is closed, the flat electronic device 15 can automatically switch to the sleep mode. The reason is explained herein. A detector can be disposed internally of the flat electronic device 15. The detector has internal magnets with alternating polarity (+ − + −), which is complemented by the opposite alternating polarity of the first magnet 10 of the securing member 121 of the base 12. When the folding cover 11 and the base 12 approach each other, the presence of the magnetic field is detected by the detector, and the flat electronic device 15 enters the sleep mode. Thus, energy saving can be achieved. In addition, the folding cover 11, the spine 14, and the base 12 of the leather case assembly 2 are bendably connected. In particular, the width of the spine 14 is greater than the thickness of the flat electronic device 15. Therefore, when the leather case is closed, the flat electronic device 15 can be received and protected effectively.

Please refer to FIG. 3, which shows the leather case assembly 2 of the instant disclosure in use. Namely, the leather case assembly 2 integrates the keyboard 13 and the flat electronic device 15. As shown in FIG. 3, the keyboard 13 is firmly disposed in the receiving region (not shown) defined by the securing member 121 and the base 12. Correspondingly, the flat electronic device 15 is firmly secured by the first holding member 112a and the second holding member 114a on the second support portion 112 and the frame support 114. For the instant embodiment, to use the flat electronic device 15, the bending portion 113 formed between the first support portion 111 and the second support portion 112 may be bent to an obtuse angle. Meanwhile, the first magnet/magnetic member 10 is disposed on the securing member 121 of the base 12, and the second magnet/magnetic member 20 is arranged on the second holding member 114a of the frame support 114. Due to the magnetic attraction between the first magnet/magnetic member 10 and the second magnet/magnetic member 20, the support frame 114 can be firmly secured on the securing member 121 near the spine 14. In other words, the flat electronic device 15 can be firmly disposed on the securing member 121 near the spine 14, allowing the user to operate the flat electronic device 15 via the keyboard 13.

Please refer to FIG. 4, which shows another setup of the leather case assembly 2 in use for the instant disclosure. Specifically, the flat electronic device 15 is secured on the second support portion 112 and the frame support 114. Therefore, the frame support 114 can be pulled to change its position relative to the first support portion 111. Then, the frame support 114 can be abutted against the display-rest 131 on the keyboard 13. By abutting against different display—rest 131, the viewing angle of the flat electronic device 15 can be adjusted by the user for using with the keyboard 13.

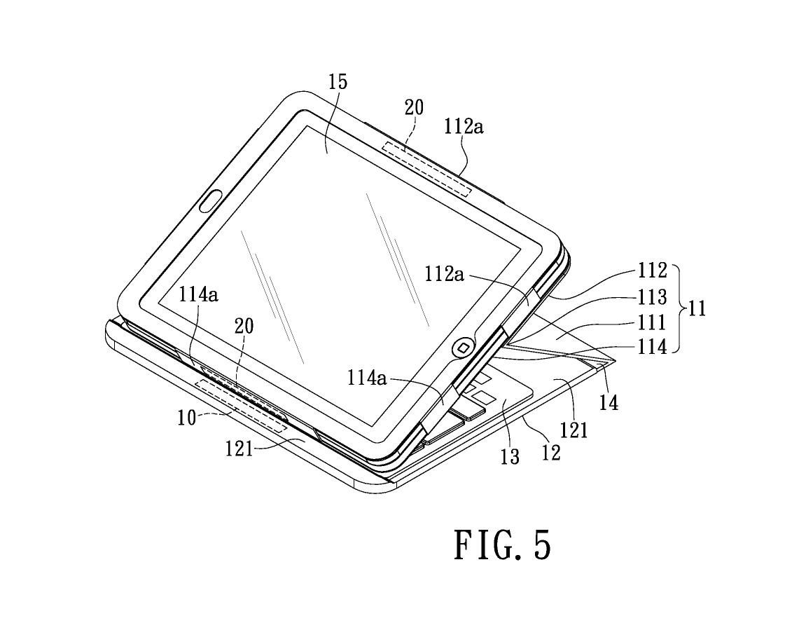

Please refer to FIG. 5, which further shows another setup of the leather case assembly 2 in use for the instant disclosure. When the user wants to operate the flat electronic device 15 without using the keyboard 13, the frame support 114 can be pulled again to further adjust the viewing angle of the flat electronic device 15. In particular, the bending portion 113 formed between the first support portion 111 and the second support portion 112 may be bent to form an acute angle. By the magnetic attraction between the first magnet/magnetic member 10 disposed on the securing member 121 of the base 12 and the second magnet/magnetic member 20 disposed on the second holding member 114a of the support frame 114, the support frame 114 can be firmly disposed on the securing member 121 away from the spine 14. Thus, the flat electronic device 15 is projected upward at its greatest extent to be operated by the user.

For advantages, the instant disclosure can adjust the viewing angle of the flat electronic device effectively, besides receive and protect the device. The inclusion of the keyboard allows the flat electronic device to be operated and carried by the user as a complete unit.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A leather case with keyboard, comprising:
a folding cover having a first support portion and a second support portion in adjustable folding connection, the second support portion including at least one first holding member;
a base foldingly connected to the first support portion having a securing member defining a receiving region; and
a removable keyboard disposed in the receiving region.

2. The leather case with keyboard of claim 1, wherein the securing member is a frame-like structure having a predetermined thickness, and wherein the frame-like structure and the base receiving region is defined by.

3. The leather case with keyboard of claim 2, wherein the securing member has at least one first magnet/magnetic member arranged thereon.

4. The leather case with keyboard of claim 3, wherein the first holding member has at least one second magnet/magnetic member arranged thereon for holding the folding cover and the base tightly together when the leather case is closed.

5. The leather case with keyboard of claim 1, wherein the width of the first support portion is greater than the width of the second support portion.

6. The leather case with keyboard of claim 1, wherein the second portion extends in forming a support frame having at least one second holding member.

7. The leather case with keyboard of claim 6, wherein the width of the support frame is equal to or less than the width of the first support portion.

8. The leather case with keyboard of claim 1, further comprising a spine bendably connected between the first support portion and the base as a pivot for closing or opening the leather case.

9. The leather case with keyboard of claim 1, wherein the keyboard has at least one third magnet/magnetic member arranged thereon, and wherein the base has at least one fourth magnet/magnetic member arranged thereon for securing the keyboard to the base by magnetic attraction.

10. The leather case with keyboard of claim 1, wherein the keyboard has at least one display-rest formed thereon.

11. A leather case assembly with keyboard, comprising:
a folding cover having a first support portion and a second support portion in adjustable folding connection, the second support portion including at least one first holding member;
a base foldingly connected to the first support portion having a securing member defining a receiving region;
a removable keyboard disposed in the receiving region; and
a flat electronic device signal communicable with the removable keyboard secured to the folding cover by the first holding member.

12. The leather case assembly with keyboard of claim 11, wherein the securing member is a frame-like structure having a thickness, and wherein the receiving region is defined by the frame-like structure and the base.

13. The leather case assembly with keyboard of claim 12, wherein the securing member has at least one first magnet/magnetic member arranged thereon.

14. The leather case assembly with keyboard of claim 13, wherein the first holding member has at least one second magnet/magnetic member arranged thereon for holding the folding cover and the base tightly together when the leather case is closed.

15. The leather case assembly with keyboard of claim 11, wherein the width of the first support portion is greater than the width of the second support portion.

16. The leather case assembly with keyboard of claim 11, wherein the second portion extends in forming a support frame having at least one second holding member, and wherein the flat electronic device is secured by the first holding member and the second holding member.

17. The leather case assembly with keyboard of claim 16, wherein the width of the support frame is equal to or less than the width of the first support portion.

18. The leather case assembly with keyboard of claim 11, further comprising a spine bendably connected between the first support portion and the base as a pivot for closing or opening the leather case, wherein the width of the spine is greater than the thickness of the flat electronic device.

19. The leather case assembly with keyboard of claim 11, wherein the keyboard has at least one third magnet/magnetic member arranged thereon, and wherein the base has at least one fourth magnet/magnetic member arranged thereon for securing the keyboard to the base by magnetic attraction.

20. The leather case assembly with keyboard of claim 11, wherein the keyboard has at least one display-rest formed thereon.
